(19) United States
(12) Patent Application Publication
(10) Pub. No.: US 2025/0301890 A1
(43) Pub. Date: Sep. 25, 2025

(54) DISPLAY PANEL AND DISPLAY DEVICE

(71) Applicant: HKC CORPORATION LIMITED, Shenzhen (CN)

(72) Inventors: Zhengcai Hu, Shenzhen (CN); Haijiang Yuan, Shenzhen (CN)

(21) Appl. No.: 19/073,132

(22) Filed: Mar. 7, 2025

(30) Foreign Application Priority Data
Mar. 20, 2024 (CN) 202410326419.X

(51) Int. Cl. H10K 59/80; H10K 59/127

(52) U.S. Cl. CPC H10K 59/878; H10K 59/127; H10K 59/873

(57) ABSTRACT

A display panel and a display device are provided. The display panel includes a first substrate, a second substrate and an encapsulation adhesive layer. The first substrate includes a display area and a frame area. The display area is provided with a plurality of pixels. The frame area is provided with an electrode circuit. The encapsulation adhesive layer is arranged in the frame area and is located between the electrode circuit and the second substrate. An optical structure is provided on the second substrate, and the optical structure is capable of reflecting or refracting light at an inner side and/or an outer side of the encapsulation adhesive layer to a contact interface between the encapsulation adhesive layer and the second substrate.

### CROSS-REFERENCE TO RELATED APPLICATION

Pursuant to 35 U.S.C. § 119 and the Paris Convention, this application claims the benefit of Chinese Patent Application No. 202410326419. X filed on Mar. 20, 2024, the content of which is incorporated herein by reference.

### TECHNICAL FIELD

The present application relates to the field of display technology, and in particular, to a display panel and a display device.

### BACKGROUND

The statements provided herein are merely background information related to the present application, and do not necessarily constitute any prior arts. OLED (Organic Light-Emitting Diode) displays have obvious advantages in display, such as all-solid-state structure, high brightness, full viewing angle, fast response speed, low blue light, wide operating environment temperature, flexible display, etc. Currently, OLED displays are mainly used in small-size directions such as mobile phones, watches, and tablets.

The basic structure of OLED is a layer of organic electroluminescent material between two pieces of glass. The usual encapsulation method is to use glass glue (frit) to encapsulate around the organic electroluminescent material (i.e., the frame area).

The old problem still exists. Organic materials are afraid of water and oxygen, and encapsulation is still the top priority. In order to meet the needs of narrow frame and other requirements, the electrode circuits of existing OLEDs are mostly placed in the frame area and below the frit glue.

During laser sintering, the upper and lower contact surfaces of the glass powder are made of different materials (for example, glass on the top and metal on the bottom). Under the same laser energy, the metal side has a strong reflective ability of the metal surface, while the upper glass has no reflective function to the laser. The adhesion between the glass glue and the upper glass is much smaller than the adhesion between the glass glue and the metal, which results in poor encapsulation between the glass glue and the upper glass.

### SUMMARY

An objective of embodiments of the present application is to provide a display panel and a display device, aiming to solve the technical problem of poor adhesion between the encapsulation glue and the upper glass in the existing OLED.

In accordance with a first aspect of the embodiments of the present application, a display panel is provided, which includes: a first substrate, a second substrate and an encapsulation adhesive layer.

The first substrate includes a display area and a frame area, the display area is provided with a plurality of pixels, and the frame area is provided with an electrode circuit connected to each of the pixels.

The second substrate is a light-transmitting substrate, arranged opposite to the first substrate and spaced apart from the first substrate.

The encapsulation adhesive layer is arranged in the frame area and is located between the electrode circuit and the second substrate.

Where an optical structure is arranged on the second substrate, and the optical structure is capable of reflecting or refracting light at an inner side and/or an outer side of the encapsulation adhesive layer to a contact interface between the encapsulation adhesive layer and the second substrate.

In one embodiment, the optical structure includes a first reflective layer, a groove is formed on a side of the second substrate facing the encapsulation adhesive layer, the first reflective layer is arranged on at least one inner sidewall of the groove, and the encapsulation adhesive layer is connected to a bottom wall of the groove.

In one embodiment, the inner sidewall of the groove is an inner concave wall or a plane wall, and the first reflective layer is a metal layer.

In one embodiment, the optical structure includes a first reflective layer, a first convex block is provided on a side of the second substrate facing the encapsulation adhesive layer, the first convex block is located at the inner side and/or outer side of the encapsulation adhesive layer, the first reflective layer is provided on the first convex block and has a second reflective surface for reflecting light.

Or alternatively, the optical structure includes a first convex block, the first convex block is provided on the side of the second substrate facing the encapsulation adhesive layer, and is located at the inner side and/or outer side of the encapsulation adhesive layer; the first convex block has a second reflective surface for reflecting light.

In one embodiment, a material of the first convex block is same as that of the second substrate. The second reflective surface is a plane or a concave surface.

In one embodiment, the optical structure includes a second convex block, the second convex block is a transparent convex block, provided on a side of the second substrate away from the encapsulation adhesive layer and located at the inner side and/or outer side of the encapsulation adhesive layer, and the second convex block has a light incident bevel for refracting light.

In one embodiment, the light incident bevel is an inner concave surface, and a material of the second convex block is same as that of the second substrate.

In one embodiment, the electrode circuit includes a light-transmitting layer provided on the first substrate and a conductive layer provided on the light-transmitting layer, and the electrode circuit is provided with a plurality of hollow areas that at least penetrate the conductive layer in a thickness direction; the light-transmitting layer is a light-transmitting insulating material layer.

In one embodiment, a plurality of high-transmittance areas and a low-transmittance area are provided on a surface of the second substrate that is away from the first substrate, and the low-transmittance area corresponds to a non-hollow area defined by the plurality of hollow areas.

In accordance with a second aspect of the embodiments of the present application, a display device is provided, which includes the display panel described in the above embodiments.

The display panel and the display device provided by the embodiments of the present application have at least the following beneficial effects:

In the display panel, the optical structure is provided so that the light at the inner side and/or the outer side the encapsulation adhesive powder (or encapsulation adhesive powder), that is, the part of the light that originally cannot directly reach the encapsulation adhesive powder, is enabled to change its propagation direction to reach the contact interface between the encapsulation adhesive powder and the second substrate, and to be utilized. Thus, the laser energy at the upper end of the encapsulation adhesive powder is increased, which thus can enhance the bonding strength between the upper end of the encapsulation adhesive powder and the lower surface of the second substrate, and ensure a good encapsulation effect between the encapsulation adhesive powder and the second substrate.

### BRIEF DESCRIPTION OF DRAWINGS

In order to illustrate the technical solutions in the embodiments of the present application more clearly, the drawings needed to be used in the embodiments will be briefly introduced below. Obviously, the drawings described below are merely some embodiments of the present application. For a person of ordinary skill in the art, other drawings may be obtained based on these drawings on the premise of paying no creative labor.

FIG. 1 is a schematic diagram showing a structure of a display panel and a laser route during laser sintering provided in an embodiment of the present application;

FIG. 2 is a step S1 of making a groove on the second substrate in the display panel of FIG. 1;

FIG. 3 is a step S2 of making the groove on the second substrate in the display panel of FIG. 1;

FIG. 4 is a step S3 of making the groove on the second substrate in the display panel of FIG. 1;

FIG. 5 is a schematic diagram of a structure of a display panel and a laser route during laser sintering provided in an embodiment of the present application;

FIG. 6 is a step T1 of making a first convex block on the second substrate in the display panel of FIG. 5;

FIG. 7 is a step T2 of making the first convex block on the second substrate in the display panel of FIG. 5;

FIG. 8 is a schematic diagram of a structure of a display panel and a laser route during laser sintering provided in an embodiment of the present application;

FIG. 9 is a schematic diagram of a structure of a display panel provided in an embodiment of the present application;

FIG. 10 is a schematic diagram of a laser route of the display panel of FIG. 9 during laser sintering;

FIG. 11 is a schematic diagram of a structure of a display panel provided in an embodiment of the present application;

FIG. 12 is a schematic diagram of a laser route of the display panel of FIG. 11 during laser sintering; and

FIG. 13 is a schematic diagram of a structure of the display device provided in an embodiment of the present application.

Reference signs in the figures are illustrated as follows:
100—display panel;
1—first substrate, 11—display area, 12—frame area;
2—second substrate, 21—high-transmittance area, 22—low-transmittance area, 23—light-blocking layer, 24—groove, 241—first inner sidewall, 242—second inner sidewall;
251—first reflective layer, 2510—first reflective surface, 2518—deposition material;
253—first convex block, 2531—second reflective layer, 2530—second reflective surface;
255—second convex block, 2550—light incident bevel;
3—encapsulation adhesive layer;
4—electrode circuit, 41—hollow area, 42—non-hollow area, 43—conductive layer, 44—light-transmitting layer;
200—display device, 91—power supply, 92—control circuit.

### DETAILED DESCRIPTION OF EMBODIMENTS

In order to make the objectives, technical solutions and advantages of the present application more comprehensible and clearer, the present application is further described in detail in conjunction with the drawings and embodiments. It should be understood that the specific embodiments described herein are only used to explain the present application and are not intended to limit the present application.

It should be noted that when a component is referred to as “fixed on” or “arranged on” another component, it may be directly or indirectly fixed or arranged on the other component. When a component is referred to as “connected to” another component, it may be directly or indirectly connected to the other component. The orientation or position relationship indicated by the terms “upper”, “lower”, “left”, “right”, etc. is based on the orientation or position relationship shown in the drawings, which is only for the convenience of description, and does not indicate or imply that the device or element referred to must have a specific orientation, or be constructed and operated in a specific orientation, and thus cannot be understood as a limitation on this patent. The terms “first” and “second” are only used for description purposes, and cannot be understood as indicating or implying relative importance or implicitly indicating the number of technical features. The phrase “a/the plurality of” means two or more, unless otherwise expressly specified.

To illustrate the technical solutions described in the present application, a detailed description will be given below with reference to specific drawings and embodiments.

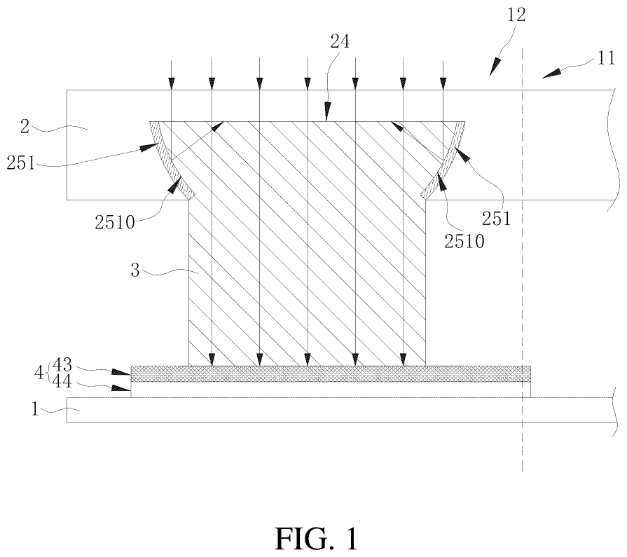

First, referring to FIG. 1. an embodiment of the present application provides a display panel 100, which includes a first substrate 1 and a second substrate 2 that are arranged oppositely and spaced apart. The first substrate 1 and the second substrate 2 are both divided into a display area 11 and a frame area 12. The frame area 12 is located around the display area 11. A plurality of pixels (not shown) are arranged in the display area 11. The frame area 12 is provided with an electrode circuit 4 connected to each pixel. The display panel 100 also includes an encapsulation adhesive layer 3, the encapsulation adhesive layer 3 is arranged in the frame area 12 and located between the electrode circuit 4 and the second substrate 2, and is configured to encapsulate the electrode circuit 4 and the second substrate 2 as one, that is, to encapsulate the first substrate 1 and the second substrate 2 as one.

Here, for the convenience of description and understanding below, two directions of “up” and “down” are defined, the second substrate 2 is located at the top, and the first substrate 1 is located at the bottom. In addition, two directions of “inside” and “outside” are defined, and the display area 11 is located at the inner side of the frame area 12.

In this embodiment, the display panel 100 also includes an optical structure disposed on the second substrate 2 and located inside and/or outside the encapsulation adhesive layer 3, and the optical structure is capable of reflecting or refracting light at an inner side and/or an outer side of the encapsulation adhesive layer 3 to a contact interface between the encapsulation adhesive layer 3 and the second substrate 2, that is, between an upper end of the encapsulation adhesive layer 3 and the second substrate 2.

In the display panel 100 of this embodiment, during encapsulation, encapsulation adhesive powder (for example, glass powder) in a non-molten state is sandwiched between the electrode circuit 4 and the second substrate 2, and the encapsulation adhesive powder is irradiated by using a laser from above the second substrate 2. A first part of the laser is transmitted from the second substrate 2 (the second substrate 2 is a light-transmitting substrate) and reaches the upper end of the encapsulation adhesive powder; a second part of the laser continues downward to reach the electrode circuit 4 (the electrode circuit 4 is non-transparent) and is reflected back to a lower end of the encapsulation adhesive powder; and a third part of the laser, that is, the laser at the inner side and/or the outer side of the encapsulation adhesive powder, cannot reach down to the first substrate 1, but is reflected or refracted by the optical structure and reaches the upper end of the encapsulation adhesive powder, as shown in FIG. 1 (the straight arrow in FIG. 1 represents the laser).

The laser energy enables the encapsulation adhesive powder to be melt and bond with the electrode circuit 4 and the second substrate 2. After cooling and curing, the encapsulation adhesive layer 3 is obtained.

The optical structure is arranged in such a way that the light at the inner side and/or the outer side of the encapsulation adhesive layer 3 (or the encapsulation adhesive powder), that is, the part of light that originally could not directly reach the encapsulation adhesive powder, is enabled to change the propagation direction and reach the contact interface between the encapsulation adhesive powder and the second substrate 2 and be utilized. Thereby, the laser energy at the upper end of the encapsulation adhesive powder is increased, which can improve the bonding strength between the upper end of the encapsulation adhesive layer 3 and the lower surface of the second substrate 2, and ensure a good encapsulation effect between the encapsulation adhesive layer 3 and the second substrate 2.

The second substrate 2 is a light-transmitting substrate, specifically a glass substrate. It should be understood that, according to needs, the second substrate 2 may also be a light-transmitting substrate of other materials that can withstand the high temperature of laser sintering.

The first substrate 1 may be a light-transmitting substrate, such as a glass substrate, or may be a non-transparent substrate, such as a metal oxide substrate. In an exemplary embodiment, the optical structure is a reflective structure.

Specifically, as shown in FIG. 1, a groove 24 is formed on a lower side of the second substrate 2, and a portion of the encapsulation adhesive layer 3 is disposed in the groove 24. A bottom wall of the groove 24 is configured to contact and bond with the upper end of the encapsulation adhesive layer 3. The groove 24 is large inside and has a small opening, so that at least one inner sidewall of the groove 24 is inclined from bottom to top in a direction gradually away from the encapsulation adhesive layer 3, and a first reflection layer 251 is disposed on the inner sidewall, and a surface of the first reflection layer 251 serves as a first reflection surface 2510 for reflecting light.

Moreover, an inclined inner sidewall of the groove 24 causes the bottom wall of the groove 24 to be substantially lengthened, which increases a contact area between the encapsulation adhesive layer 3 and the second substrate 2, and thus can further improve the bonding strength between the encapsulation adhesive layer 3 and the second substrate 2.

In one embodiment, the groove 24 has a first inner sidewall 241 away from the display area 11 and a second inner sidewall 242 close to the display area 11. It may be possible that only the first inner sidewall 241 is inclined and provided with a first reflective layer 251, or only the second inner sidewall 242 is inclined and provided with a first reflective layer 251, or both the first inner sidewall 241 and the second inner sidewall 242 are inclined and provided with a first reflective layer 251.

The first reflective layer 251 may be made of a material that can be stably attached to the inner sidewall of the groove 24 and has good reflectivity. For example, the first reflective layer 251 may be a metal layer, such as an aluminum layer, a copper layer, a titanium layer, etc. Or alternatively, the first reflective layer 251 may be a non-metal layer, such as an inorganic non-metal material layer, such as a ceramic layer, etc.

The inner sidewall of the groove 24 may be an inner concave wall, and accordingly, the first reflective surface 2510 may be a concave surface. The concave surface has a concentrating effect on light. Alternatively, the inner sidewall of the groove 24 may be an outer convex wall, and accordingly, the first reflection surface 2510 may be a convex surface. The convex surface has a divergent effect on light. Alternatively, the inner sidewall of the groove 24 may be a plane, and accordingly, the first reflection surface 2510 may be a plane.

In practical applications, the inner sidewall of the groove 24 may be selected as needed. Moreover, when the groove 24 has two first reflection surfaces 2510, the shapes of the two first reflection surfaces 2510 may be the same (referring to mirror symmetry here) or different.

In the present application, the inner sidewall of the groove 24 and the first reflection surface 2510 may be concave or flat, which can simultaneously ensure laser reflection and utilization efficiency, and conform to the process.

The first reflection layer 251 may be formed by physical vapor deposition, chemical vapor deposition, spraying, etc.

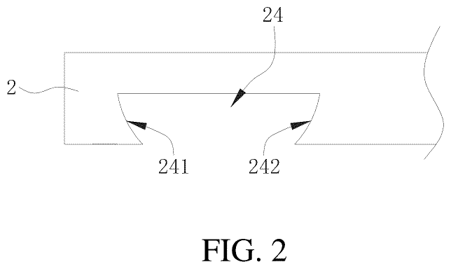

Referring to FIGS. 2 to 4, and specific production steps of the groove 24 and the reflection layer of the metal material may be referred to as follows:

In step S1, as shown in FIG. 2, a lower surface of the second substrate 2 is etched to form a groove 24. In this step S1, gas etching may be specifically used to remove part of the material on the surface of the second substrate 2 by ion bombardment and chemical reaction under the plasma system. By controlling the direction and intensity of the ion beam, the groove 24 of a desired shape may be obtained. Alternatively, in this step S1, the groove 24 may be specifically formed by mechanical processing.

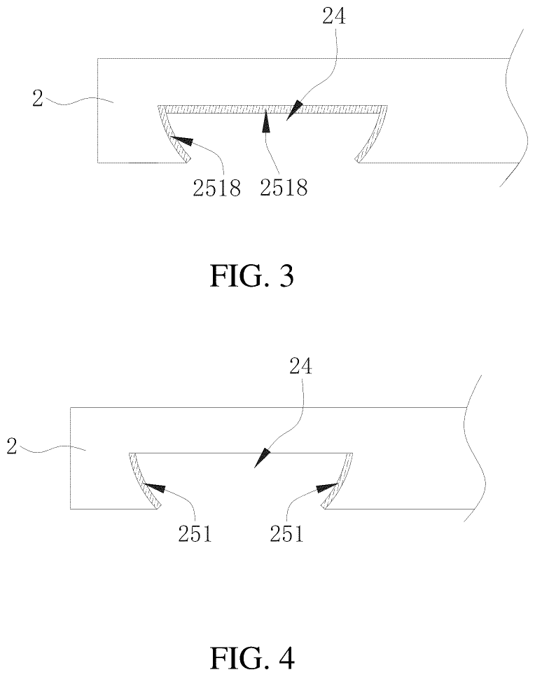

In step S2, as shown in FIG. 3, a layer of material is deposited in the groove 24 to obtain a deposited material 2518 on the bottom wall and the inner sidewall of the groove 24.

Thus, in step S3, as shown in FIG. 4, part of the deposited material 2518 on the bottom wall of the groove 24 is etched to obtain a bottom wall that can transmit light and a first reflective layer 251 on the inner sidewall. Specifically, the first reflective layer 251 is a metal material, and in this step S3, wet etching may be used.

In some embodiments of the present application, the optical structure may be a deformed reflective structure.

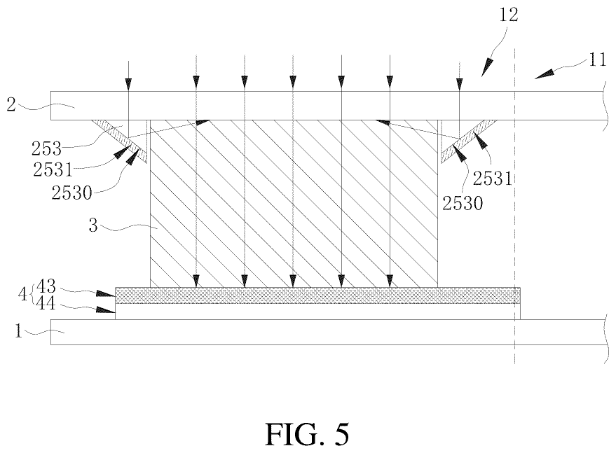

As shown in FIG. 5, a first convex block 253 is provided on the lower surface of the second substrate 2, and the first convex block 253 is located at the inner side and/or outer side of the encapsulation adhesive layer 3, and the first convex block 253 has a second reflective surface 2530 for reflecting light.

Optionally, the first convex block 253 may be formed only on the inner side of the encapsulation adhesive layer 3. Alternatively, the first convex block 253 may be formed only on the outer side of the encapsulation adhesive layer 3. Or alternatively, the first convex block 253 may be formed on both the outer side and the inner side of the encapsulation adhesive layer 3.

In one embodiment, the second reflective surface 2530 may be provided on a side surface of the first convex block 253 facing the encapsulation adhesive layer 3. In this way, the laser, when reaching the side surface of the first convex block 253 after transmitted from the second substrate 2, is reflected and will not enter the first convex block 253. In this case, the first convex block 253 may be made of an integral light-tight material, such as a metal material, or the first convex block 253 may be a light-transmitting material, and the second reflective surface 2530 is formed by the surface of the second reflective layer 2531 attached to the surface of the first convex block 253.

In another embodiment, the second reflective surface 2530 may be arranged on a side surface of the first convex block 253 away from the encapsulation adhesive layer 3, as shown in FIG. 5. In this case, the first convex block 253 is made of a light-transmitting material, and the second reflective surface 2530 is formed by the surface of the second reflective layer 2531 attached to the surface of the first convex block 253. As shown in FIG. 5, the third part of the laser, after transmitted from the second substrate 2, continues to be transmitted into the first convex block 253, and then is reflected by the second reflective surface 2530. Finally, the laser transmitted from the first convex block 253 is entered into the encapsulation adhesive powder.

Optionally, the material of the first convex block 253 is the same as that of the second substrate 2.

The second reflective surface 2530 may be a concave surface. The concave surface has a concentrating effect on light. Alternatively, the second reflective surface 2530 may be a convex surface. The convex surface has a divergent effect on light. Or alternatively, the second reflective surface 2530 may be a plane.

In practical applications, the shape of the second reflective surface 2530 may be selected as needed. Moreover, when the lower surface of the second substrate 2 has two first convex blocks 253, the shapes of the two second reflective surfaces 2530 may be the same (referring to mirror symmetry here) or different.

Optionally, the second reflective surface 2530 may be a concave surface or a plane, which can simultaneously ensure laser reflection and utilization efficiency and conform to the process.

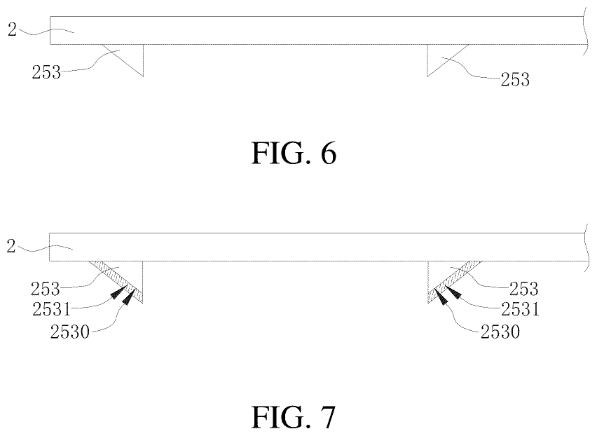

Referring to FIGS. 6 and 7, and the production method of the first convex block 253 and the second reflective surface 2530 of the first convex block 253 may be referred to as follows:

As shown in FIG. 6, in step T1, two first convex blocks 253 are formed on the lower surface of the second substrate 2. Specifically, in the step T1, the first convex block 253 may be formed by physical vapor deposition, chemical vapor deposition, mechanical cutting, etc.

When the first convex block 253 is a light-transmitting material, as shown in FIG. 7, step T2 is also included, in which a second reflective layer 2531 is formed on the first convex block 253 to obtain a second reflective surface 2530. Specifically, in the step T2, the second reflective layer 2531 may be formed by physical vapor deposition, chemical vapor deposition or coating.

In some embodiments of the present application, a deformed optical structure is provided, which is a refractive structure.

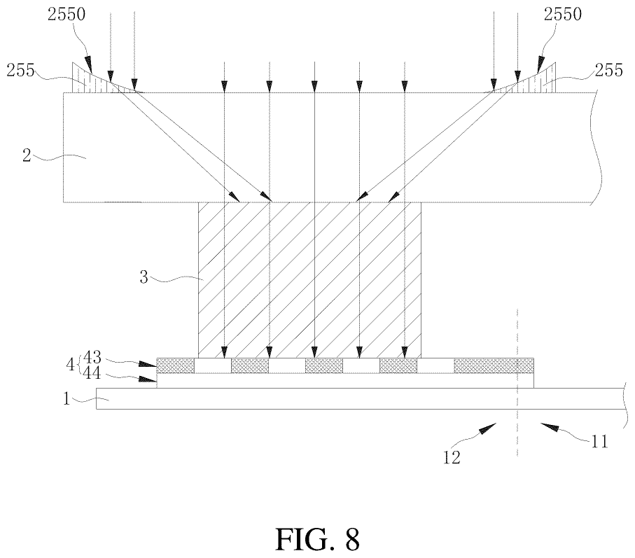

Referring to FIG. 8, a second convex block 255 is provided on the upper surface of the second substrate 2, and the second convex block 255 is a transparent convex block, which is located at the inner side and/or the outer side of the encapsulation adhesive layer 3, and the second convex block 255 has a light incident bevel 2550 for refracting light.

Specifically, the light incident bevel 2550 of the second convex block 255 is gradually approaching the encapsulation adhesive layer 3 from top to bottom. Thus, when the laser is irradiated from above the light incident bevel 2550, the laser, via a refraction of the light incident bevel 2550, is entered into the second convex block 255 and the propagation direction of the laser is changed until the interface between the encapsulation adhesive powder and the second substrate 2 is reached.

The light incident bevel 2550 may be a concave surface. The concave surface has a concentrating effect on light. Alternatively, the light incident bevel 2550 may be a convex surface, which has a divergent effect on the light. Or alternatively, the light incident bevel 2550 may be a plane.

In practical applications, the shape of the light incident bevel 2550 may be selected as needed. Moreover, when the lower surface of the second substrate 2 has two second convex blocks 255, the shapes of the two light incident bevels 2550 may be the same (referring to mirror symmetry here) or different.

Optionally, the light incident bevel 2550 may be a concave surface or a plane, which can simultaneously ensure laser reflection and utilization efficiency, and conform to the process.

In this embodiment, the second convex block 255 may also be formed by physical vapor deposition, chemical vapor deposition, mechanical cutting, etc.

In the actual process, based on the electrical connection relationship between the electrode circuit 4 and pixels, and in order to optimize the process and reduce steps, the electrode circuit 4 of the frame area 12 is formed in the same layer and the same material as the pattern of the display area 11.

Currently, the material of the electrode circuit 4 is usually a composite layer of multiple metals. For example, the electrode circuit 4 is in the same layer as the source and drain, and has a composite material of multiple materials such as aluminum (Al), molybdenum (Mo), copper (Cu), and titanium (Ti) to take into account low resistance and anti-oxidation functions. The problem brought about by this is that due to the different thermal expansion coefficients of different metal materials, different metal material layers will expand to different degrees during laser sintering. For example, Al has a lower resistivity, but the expansion of aluminum layer when heated will be more obvious. After sintering and cooling, the surface of aluminum layer will have sharp protrusions or hillocks, which will cause hillocks on the surface of the electrode circuit 4, which further leads to poor adhesion between the glass glue layer and the electrode circuit 4, and the material layers of the electrode circuit 4 itself are also prone to poor contact.

Thus, in the related arts, to reduce the hillock phenomenon on the surface of the electrode circuit 4, to ensure the contact between the glass glue layer and the electrode circuit 4 and the conductive property of the electrode circuit 4 itself, the laser energy used for sintering is usually reduced to ensure that the temperature is maintained at a level that does not cause the hillock phenomenon during the laser sintering process.

The reduction of laser energy will inevitably lead to limited bonding strength between the encapsulation adhesive layer 3 and the second substrate 2.

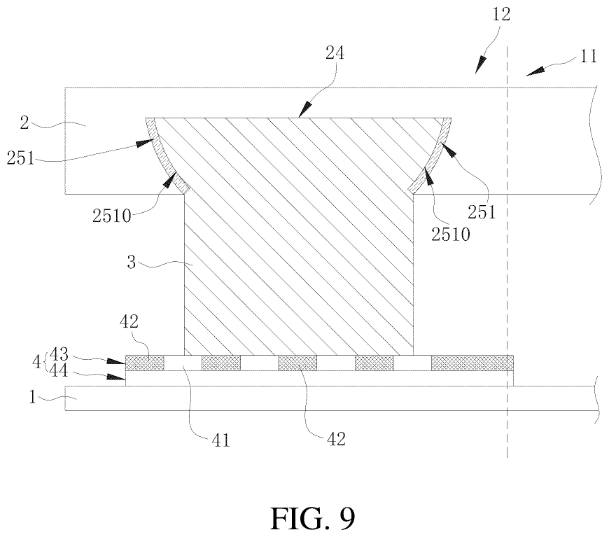

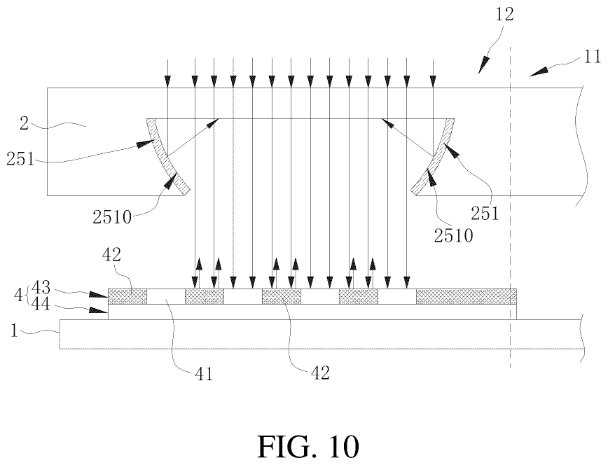

As shown in FIGS. 9 and 10, on the basis of the aforementioned embodiments, a plurality of hollow areas 41 are provided on the electrode circuit 4. The reserved parts between the hollow areas 41 and the hollow areas 41 are connected to each other as a non-hollow area 42 that is used for conduction; the surface of the non-hollow area 42 facing the second substrate 2, that is, an upper surface of the non-hollow area 42, is a reflective surface.

The display panel 100 provided in this embodiment, during encapsulation, the non-molten encapsulation adhesive powder is sandwiched between the electrode circuit 4 and the second substrate 2, and the encapsulation adhesive powder is irradiated by using a laser from above the second substrate 2. The first part of the laser is transmitted from the second substrate 2 (the second substrate 2 is a light-transmitting substrate) and reaches the upper end of the encapsulation adhesive powder. The second part of the laser continues downward to reach the electrode circuit 4. The reflection surface of the non-hollow area 42 reflects part of the laser upward back to the lower end of the encapsulation adhesive powder, and the hollow area 41 allows the laser to continue to reach the second substrate 2 downward, as shown in FIG. 10. For the path of the third part of the laser, references may be made to the above embodiments, which will not be repeated.

In this embodiment, a plurality of hollow areas 41 are provided on the electrode circuit 4. The provision of the hollow areas 41 actually achieves a division of the electrode circuit 4, which enables the width of the electrode circuit 4 to be smaller. In this way, in the process of laser sintering to form the encapsulation adhesive layer 3, the overall laser energy irradiated on the electrode circuit 4 is reduced, and the heat dissipation of the electrode circuit 4 can be improved, which can avoid or alleviate the hillock phenomenon of one of the metal layers (especially the metal layer with a large thermal expansion coefficient) of the electrode circuit 4 at high temperature, and ensure the contact area between the encapsulation adhesive layer 3 and the electrode circuit 4, as well as the electrical conductivity of the electrode circuit 4 itself. On this basis, it is allowed to use a laser with a larger energy for irradiation, which is conducive to improving the adhesion between the encapsulation adhesive layer 3 and the second substrate 2, and finally, ensuring the encapsulation effect of the upper and lower sides of the encapsulation adhesive layer 3, and ensuring the good encapsulation effect of the display panel 100.

In this embodiment, the electrode circuit 4 includes multiple metal layers of different materials.

For example, the electrode circuit 4 is a composite material layer of various materials such as aluminum (Al), molybdenum (Mo), and titanium (Ti).

In a specific embodiment, the electrode circuit 4 is a Ti/Al composite layer, or a Ti/Al/Ti composite layer, or a Mo/Al composite layer, or a Mo/Al/Mo composite layer. Among them, Al has a low resistivity, but a large thermal expansion coefficient, and Mo and Ti are relatively stable and have strong anti-oxidation ability, respectively serving as protective metal layers (not shown).

In other embodiments, the electrode circuit 4 may be a composite layer of multiple other materials, for example, Al is replaced with other materials with lower resistivity, and Mo and Ti are replaced with other relatively stable materials.

In one embodiment, as shown in FIGS. 1 and 2, the electrode circuit 4 includes a conductive layer 43 and a light-transmitting layer 44 located below the conductive layer 43. The light-transmitting layer 44 has a light-transmitting insulating material, and the conductive layer 43 has a non-light-transmitting conductive material. That is, the aforementioned “multiple metal layers of different materials” serve as a conductive layer 43, which plays the role of electrically connecting each pixel. Here, the light-transmitting insulating material is provided mainly to be formed at the same time and in the same layer as the light-transmitting structural layer (such as a gate insulating layer) in the display area 11, that is, the mask is not required when forming the light-transmitting structural layer in the display area 11. In addition, the light-transmitting structure layer is arranged here, which can also isolate the second substrate 2 and the conductive layer 43, reduce the thermal impact on the conductive layer 43 caused by the second substrate 2 heating up after absorbing part of the laser, and further alleviate the hillock phenomenon of the conductive layer 43.

The hollow areas 41 penetrate the conductive layer 43 along the thickness direction, but do not penetrate the light-transmitting layer 44. Alternatively, the hollow areas 41 penetrate both the conductive layer 43 and the light-transmitting layer 44 along the thickness direction. The penetration or non-penetration of the light-transmitting layer 44 does not affect the laser reaching the first substrate 1 after irradiating downward here.

The light-transmitting layer 44 may be a silicon nitride (SiNx) layer, or a silicon oxide (SiOx) layer, or a composite layer of the two materials of silicon nitride and silicon oxide.

It should also be understood that, according to the specific implementation, the light-transmitting layer 44 may also be omitted in other optional embodiments.

The width of the electrode circuit 4 is not specifically limited. Generally, the wider the electrode circuit 4, the smaller the resistance. Thus, the width setting of the electrode circuit 4 should take into account its good conductive performance.

The hollow area 41 may be formed by etching. Specifically, the pixels in the display area 11 include a conductive structure layer of the same layer and the same material as the conductive layer 43. Taking the source and drain as examples, a patterned conductive structure layer and the conductive layer 43 are formed simultaneously in a photolithography process.

Alternatively, the hollow areas 41 may be formed by post-processing. Specifically, mechanical punching or laser punching.

The side length of the hollow area 41 is greater than or equal to 10 microns. Optionally, the side length of the hollow area 41 is greater than or equal to 20 microns.

The shape of the hollow area 41 is not limited. For example, the shape of the hollow area 41 may be rectangular, circular, elliptical or other circular shapes, or other regular or irregular shapes. In general, the selection of the shape of the hollow area 41 should take into account the good conductivity of the conductive layer 43 as well as the convenience of implementation in the actual process.

On the electrode circuit 4, the setting of the sum of the areas of all hollow areas 41 should take into account the good conductivity of the conductive layer 43. Since the setting of the hollow areas 41 will increase the resistance of the conductive layer 43, the hollow areas 41 should not be too large. In one embodiment, assuming that the sum of the areas of all hollow areas 41 is A and the area of the electrode circuit 4 is B, then A/B≤0.5, optionally, A/B<0.4, further optionally, A/B≤0.3, and further optionally, A/B≤0.2.

As shown in FIG. 1, the outer side surface of the encapsulation adhesive layer 3 is flush with the outer side surface of the electrode circuit 4, or alternatively, the outer side surface of the encapsulation adhesive layer 3 is located outside the electrode circuit 4, that is, the encapsulation adhesive layer 3 covers the outer side surface of the electrode circuit 4. The inner side surface of the electrode circuit 4 is extended into the display area 11 and is in electrical connection with each pixel.

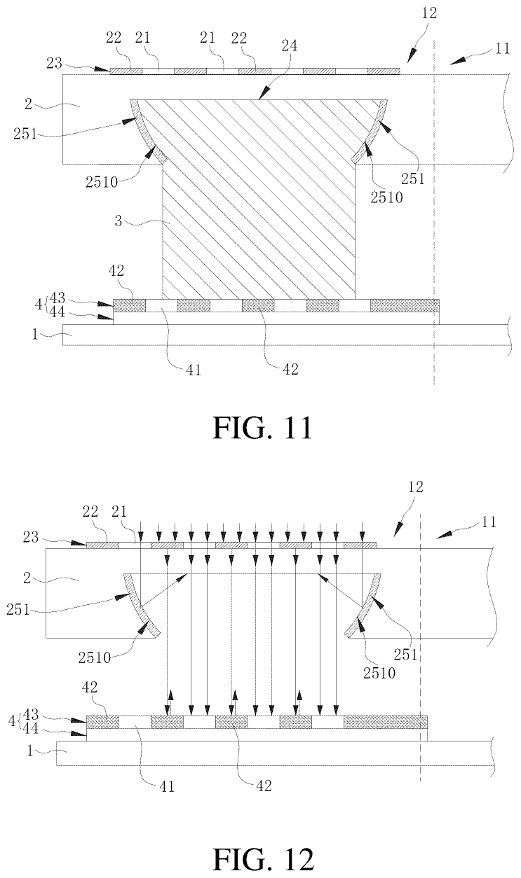

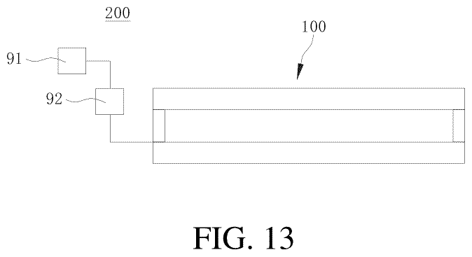

As shown in FIG. 11 and FIG. 12, on the basis of the above embodiments, the upper surface of the second substrate 2 is provided with a plurality of high-transmittance areas 21 and a low-transmittance area 22, the low-transmittance area 22 corresponds to the non-hollow area 42, and the high-transmittance areas 21 correspond to the hollow areas 41.

In this embodiment, the transmittance of the low-transmittance area 22 is smaller than that of the high-transmittance area 21, which is configured to further filter a part of the laser energy and reduce the laser irradiated to the non-hollow area 42. Such a configuration is aimed to further increase the energy of the laser irradiated on the second substrate 2, so as to improve the bonding force between the second substrate 2 and the encapsulation adhesive layer 3 without aggravating the hillock problem of the conductive layer 43.

In one embodiment, the projection of the low-transmittance area 22 along the up-down direction coincides with the non-hollow area 42 (the size and shape are exactly the same), or the projection of the low-transmittance area 22 along the up-down direction may completely cover the non-hollow area 42, and also partially cover the hollow area 41. It should be noted that, limited by the actual manufacturing process, in actual applications, a certain distance between the projection of the low-transmittance area 22 and any edge of the non-hollow area 42 is also acceptable.

In an optional embodiment, the low-transmittance area 22 may be formed integrally on the upper surface of the second substrate 2, that is, the high-transmittance area 21 and the low-transmittance area 22 may be directly obtained by processing the upper surface of the second substrate 2, such as by frosting, acid etching, etc., so that the upper surface of the second substrate 2 forms some relatively fuzzy, low-transmittance areas, which serve as the low-transmittance area 22.

In an optional embodiment, the low-transmittance area 22 may be formed by an additional light-blocking layer 23 formed on the upper surface of the second substrate 2. Specifically, for example, a spraying/printing, where a liquid is sprayed or a specific pattern is printed on the surface of the second substrate 2 to obtain a thinner covering layer. Or alternatively, a film pasting, where a film layer having an opaque effect is attached to the surface of the second substrate 2.

The high-transmittance areas 21 may be the upper surface of the second substrate 2, that is, the portions of the upper surface of the second substrate 2 that are not processed in any way may be used as the high-transmittance areas 21.

As shown in FIG. 13, an embodiment of the present application provides a display device 200, including the display panel 100 described in any of the above embodiments. In addition, the display device 200 may also include a power supply 91 electrically connected and a control circuit 92, and the control circuit 92 is further connected to each electrode circuit 4 to control a voltage on each electrode circuit 4, so as to control a switch-on or a switch-off of each pixel.

The display device 200 provided in this embodiment has the same technical effects as the display panel 100 described in the above embodiments, and will not be described in detail.

The above description is only some preferred embodiment of the present application, and is not intended to limit the present application. Any modifications, equivalent substitutions and improvements made within the spirit and principles of the present application shall all be included within the protection scope of the present application.

What is claimed is:

1. A display panel, comprising:
a first substrate, comprising a display area and a frame area, the display area provided with a plurality of pixels, and the frame area provided with an electrode circuit connected to each of the plurality of pixels;
a second substrate, being a light-transmitting substrate, arranged opposite to the first substrate and spaced apart from the first substrate; and
an encapsulation adhesive layer, arranged in the frame area and located between the electrode circuit and the second substrate;
wherein an optical structure is arranged on the second substrate, and the optical structure is capable of reflecting or refracting light at an inner side and/or an outer side of the encapsulation adhesive layer to a contact interface between the encapsulation adhesive layer and the second substrate.

2. The display panel according to claim 1, wherein the optical structure comprises a first reflective layer, a groove is formed on a side of the second substrate facing the encapsulation adhesive layer, the first reflective layer is arranged on at least one inner sidewall of the groove, and the encapsulation adhesive layer is connected to a bottom wall of the groove.

3. The display panel according to claim 2, wherein the at least one inner sidewall of the groove is an inner concave wall or a plane wall, and the first reflective layer is a metal layer.

4. The display panel according to claim 1, wherein the optical structure comprises a first reflective layer, a first convex block is provided on a side of the second substrate facing the encapsulation adhesive layer, the first convex block is located at the inner side and/or the outer side of the encapsulation adhesive layer, and the first reflective layer is provided on the first convex block and has a second reflective surface for reflecting light;
or alternatively, the optical structure comprises a first convex block, the first convex block is provided on the side of the second substrate facing the encapsulation adhesive layer and is located at the inner side and/or the outer side of the encapsulation adhesive layer, and the first convex block has a second reflective surface for reflecting light.

5. The display panel according to claim 4, wherein a material of the first convex block is same as that of the second substrate, and the second reflective surface is a plane or a concave surface.

6. The display panel according to claim 1, wherein the optical structure comprises a second convex block, the second convex block is a transparent convex block, provided on a side of the second substrate away from the encapsulation adhesive layer and located at the inner side and/or the outer side of the encapsulation adhesive layer, and the second convex block has a light incident bevel for refracting light.

7. The display panel according to claim 6, wherein the light incident bevel is an inner concave surface, and a material of the second convex block is same as that of the second substrate.

8. The display panel according to claim 1, wherein the electrode circuit comprises a light-transmitting layer provided on the first substrate and a conductive layer provided on the light-transmitting layer, and the electrode circuit is provided with a plurality of hollow areas that at least penetrate the conductive layer in a thickness direction; the light-transmitting layer is a light-transmitting insulating material layer.

9. The display panel according to claim 8, wherein a plurality of high-transmittance areas and a low-transmittance area are provided on a surface of the second substrate facing away from the first substrate, and the low-transmittance area corresponds to a non-hollow area defined by the plurality of hollow areas.

10. A display device, comprising:
a display panel, comprising:
a first substrate, comprising a display area and a frame area, the display area provided with a plurality of pixels, and the frame area provided with an electrode circuit connected to each of the plurality of pixels;
a second substrate, being a light-transmitting substrate, arranged opposite to the first substrate and spaced apart from the first substrate; and
an encapsulation adhesive layer, arranged in the frame area and located between the electrode circuit and the second substrate;
wherein an optical structure is arranged on the second substrate, and the optical structure is capable of reflecting or refracting light at an inner side and/or an outer side of the encapsulation adhesive layer to a contact interface between the encapsulation adhesive layer and the second substrate.

11. The display device according to claim 10, wherein the optical structure comprises a first reflective layer, a groove is formed on a side of the second substrate facing the encapsulation adhesive layer, the first reflective layer is arranged on at least one inner sidewall of the groove, and the encapsulation adhesive layer is connected to a bottom wall of the groove.

12. The display device according to claim 11, wherein the at least one inner sidewall of the groove is an inner concave wall or a plane wall, and the first reflective layer is a metal layer.

13. The display device according to claim 10, wherein the optical structure comprises a first reflective layer, a first convex block is provided on a side of the second substrate facing the encapsulation adhesive layer, the first convex block is located at the inner side and/or the outer side of the encapsulation adhesive layer, and the first reflective layer is provided on the first convex block and has a second reflective surface for reflecting light;
or alternatively, the optical structure comprises a first convex block, the first convex block is provided on the side of the second substrate facing the encapsulation adhesive layer and is located at the inner side and/or the outer side of the encapsulation adhesive layer, and the first convex block has a second reflective surface for reflecting light.

14. The display device according to claim 13, wherein a material of the first convex block is same as that of the second substrate, and the second reflective surface is a plane or a concave surface.

15. The display device according to claim 10, wherein the optical structure comprises a second convex block, the second convex block is a transparent convex block, provided on a side of the second substrate away from the encapsulation adhesive layer and located at the inner side and/or the outer side of the encapsulation adhesive layer, and the second convex block has a light incident bevel for refracting light.

16. The display device according to claim 15, wherein the light incident bevel is an inner concave surface, and a material of the second convex block is same as that of the second substrate.

17. The display device according to claim 10, wherein the electrode circuit comprises a light-transmitting layer provided on the first substrate and a conductive layer provided on the light-transmitting layer, and the electrode circuit is provided with a plurality of hollow areas that at least penetrate the conductive layer in a thickness direction; the light-transmitting layer is a light-transmitting insulating material layer.

18. The display device according to claim 17, wherein a plurality of high-transmittance areas and a low-transmittance area are provided on a surface of the second substrate facing away from the first substrate, and the low-transmittance area corresponds to a non-hollow area defined by the plurality of hollow areas.
